(19) United States
(12) Patent Application Publication
(10) Pub. No.: US 2023/0352905 A1
(43) Pub. Date: Nov. 2, 2023

(54) Optical Module

(71) Applicant: HISENSE BROADBAND MULTIMEDIA TECHNOLOGIES CO., LTD., Qingdao (CN)

(72) Inventors: Xiao CHEN, Qingdao (CN); Yunsong ZHAO, Qingdao (CN); Jingsi LI, Qingdao (CN); Zhicheng LIU, Qingdao (CN); Zhaosong LI, Qingdao (CN)

(73) Assignee: HISENSE BROADBAND MULTIMEDIA TECHNOLOGIES CO., LTD., Qingdao (CN)

(21) Appl. No.: 18/344,546

(22) Filed: Jun. 29, 2023

Related U.S. Application Data
(63) Continuation of application No. PCT/CN2022/095788, filed on May 27, 2022.

(30) Foreign Application Priority Data
May 28, 2021 (CN) 202121181727.6
Aug. 16, 2021 (CN) 202110937355.3

(51) Int. Cl. H01S 5/02315; H01S 5/02345; H04B 10/50

(52) U.S. Cl. CPC H01S 5/02315; H01S 5/02345; H04B 10/503

(57) ABSTRACT

Disclosed is an optical module, comprising: a light emitting component for generating and outputting signal light, including a laser; the laser includes: a laser chip for generating signal light; a substrate which is provided with a chip mounting groove in its top side, a circuit is laid on a top surface of the substrate, the laser chip is arranged in the chip mounting groove, with the laser chip being connected to the circuit via bonding wires.

### CROSS-REFERENCE TO RELATED APPLICATIONS

This application is a continuation application of PCT/CN2022/095788, filed May 27, 2022, which claims priority to Chinese Application No. 202121181727.6, filed on May 28, 2021, and Chinese Application No. 202110937355.3, filed on Aug. 16, 2021, which are incorporated herein by reference in their entireties.

### FIELD OF THE INVENTION

The present disclosure relates to the field of optical communication technologies, and in particular, to an optical module.

### BACKGROUND OF THE INVENTION

The quick development of application markets such as big data, blockchain, cloud computing, Internet of Things, and artificial intelligence has brought explosive growth to data traffic. Optical communication technology has gradually replaced the traditional electrical signal communication technology in various industries due to its many unique advantages such as fast speed, high bandwidth, and low installation cost. A semiconductor laser chip is a key device in modern optical fiber communication, and it is a device that generates laser light by using semiconductor materials as working substances. The big data traffic puts higher and higher requirements on the optical fiber communication system, especially on the high-frequency performance of semiconductor lasers.

### SUMMARY OF THE INVENTION

An embodiment of the present disclosure provides an optical module, including a light emitting component for generating and outputting signal light. The light emitting component includes a laser which includes: a laser chip for generating signal light; a ceramic substrate, which is provided with a chip mounting groove in its top side, a circuit is laid on a top surface of the substrate, the laser chip is arranged in the chip mounting groove, with the laser chip being connected to the circuit via bonding wires.

Wherein, a bottom of the chip mounting groove includes a chip carrying surface; a first deepening groove is provided at one side of the chip carrying surface, with a height difference between a bottom surface of the first deepening groove and the top surface of the substrate being greater than a height difference between the chip carrying surface and the top surface of the substrate; and/or, a second deepening groove is provided at the other side of the chip carrying surface, with the height difference between a bottom surface of the second deepening groove and the top surface of the substrate being greater than the height difference between the chip carrying surface and the top surface of the substrate; the laser chip is arranged on the chip carrying surface, and the first deepening groove and/or the second deepening groove are configured to keep out of the way of corners of the laser chip.

### BRIEF DESCRIPTION OF THE DRAWINGS

To more clearly describe the technical solutions of the present disclosure, the accompanying drawings to be used in the embodiments will be described briefly below. Apparently, other accompanying drawings may also be derived, without an inventive effort, by one of ordinary skills in the art from these accompanying drawings.

FIG. 1 is a part of a structural diagram of an optical communication system provided according to some embodiments of the present disclosure;

FIG. 2 is a partial structural diagram of a host computer provided according to some embodiments of the present disclosure;

FIG. 3 is a schematic structural diagram of an optical module provided according to some embodiments of the present disclosure;

FIG. 4 is a schematic exploded structural diagram of an optical module provided according to some embodiments of the present disclosure;

FIG. 5 is a structural outline diagram of a light emitting component provided according to some embodiments of the present disclosure;

FIG. 6 is a schematic structural diagram of a light emitting component provided according to some embodiments of the present disclosure, in which a tube base and a tube cap of the light emitting component are separate from each other;

FIG. 7 is a schematic structural diagram of a laser in an optical module according to some embodiments of the present disclosure;

FIG. 8 is a schematic structural diagram of a laser provided according to some embodiments of the present disclosure;

FIG. 9 is a schematic structural diagram of a ceramic substrate provided according to some embodiments of the present disclosure;

FIG. 10 is a schematic structural diagram of another aceramic substrate provided according to some embodiments of the present disclosure;

FIG. 11 is a schematic structural diagram of a further ceramic substrate provided according to some embodiments of the present disclosure;

FIG. 12 is a schematic structural diagram of still another aceramic substrate provided according to some embodiments of the present disclosure;

FIG. 13 is a schematic structural view after assembling a laser chip on the ceramic substrate of FIG. 12;

FIG. 14 is a schematic structural view of a ceramic substrate according to some embodiments of the present disclosure, with a chip mounting groove having been machined on the ceramic substrate;

FIG. 15 is a schematic structural view of another ceramic substrate according to some embodiments of the present disclosure, with a chip mounting groove having been machined on the ceramic substrate;

FIG. 16 is a cross-sectional view of a ceramic substrate provided according to some embodiments of the present disclosure;

FIG. 17 is a schematic structural diagram of a dual laser chip provided according to some embodiments of the present disclosure;

FIG. 18 is a schematic structural diagram of a top surface of a laser provided according to some embodiments of the present disclosure;

FIG. 19 is a schematic structural diagram of a bottom surface of a laser provided according to some embodiments of the present disclosure;

FIG. 20 is a schematic structural diagram of a top surface of another laser provided according to some embodiments of the present disclosure;

FIG. 21 is a schematic structural diagram of a bottom surface of another laser provided according to some embodiments of the present disclosure.

### DETAILED DESCRIPTION OF THE EMBODIMENTS

Hereinafter, technical solutions in some embodiments of the present disclosure will be described clearly and completely with reference to the accompanying drawings. Obviously, the described embodiments merely show some but not all embodiments of the present disclosure. All other embodiments obtained by a person of ordinary skill in the art based on the embodiments of the present disclosure shall fall within the protection scope of the present disclosure.

Throughout the specification and claims, unless the context requires otherwise, the term “comprise” and other forms such as the third person singular “comprises” and the present participle “comprising” are interpreted as the meaning of openness and inclusion, that is, “including, but not limited to”. In the description of the specification, the terms “one embodiment”, “some embodiments”, “exemplary embodiment(s)”, “an example”, “a specific example” or “some examples” etc. are intended to indicate that specific features, structures, materials or properties related to the embodiment(s) or example(s) are comprised in at least one embodiment or example of the present disclosure. Schematic representations of the above terms do not necessarily refer to the same embodiment(s) or example(s). In addition, the specific features, structures, materials or characteristics described may be comprised in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, features defined with “first” and “second” may explicitly or implicitly comprise one or more of the features. In the description of the embodiments of the present disclosure, “plurality” means two or more unless otherwise specified.

In describing some embodiments, the expressions “coupled” and “connected” and their derivatives may be used. For example, the term “connected” may be used in the description of some embodiments to indicate that two or more parts are in direct physical or electrical contact with each other. As another example, the term “coupled” may be used in the description of some embodiments to indicate that two or more parts are in direct physical or electrical contact. However, the terms “coupled” or “communicatively coupled” may also mean that two or more parts are not in direct contact with each other, but still cooperate or interact with each other. The embodiments disclosed herein are not necessarily limited by the contents herein.

“At least one of A, B and C” has the same meaning as “at least one of A, B or C” and both include the following combinations of A, B and C: A only, B only, C only, a combination of A and B, a combination of A and C, a combination of B and C, and a combination of A, B and C.

“A and/or B” includes the following three combinations: A only, B only, and a combination of A and B.

The use of “suitable for” or “configured to” herein means open and inclusive language that does not exclude devices that are suitable for or configured to perform additional tasks or steps.

As used herein, “about”, “substantially” or “approximately” includes the mentioned value as well as the average within an acceptable deviation range of the specified value, wherein the acceptable deviation range is as determined by one of ordinary skill in the art taking into account the measurement in question and the errors associated with the measurement of a particular quantity (i.e., limitations of the measurement system).

In optical communication technology, in order to establish information transmission between information processing devices, it is necessary to load information into light and realize information transmission via light transmission. Here, the light loaded with information is exactly the optical signal. When optical signals are transmitted in information transmission devices, a loss of optical power may be reduced, so a high-speed, long-distance, and low-cost information transmission can be realized. Signals that can be recognized and processed by an information processing device are electrical signals. Conventional information processing devices may include optical network terminals (Optical Network Unit, ONU), gateways, routers, switches, mobile phones, computers, servers, tablet computers, TVs, etc. Information transmission devices usually include optical fibers, optical waveguides, etc.

An optical module can realize mutual conversion of optical signals and electrical signals between an information processing device and an information transmission device. For example, at least one of an optical signal input port or an optical signal output port of the optical module is connected to an optical fiber, and at least one of an electrical signal input port or an electrical signal output port of the optical module is connected to an optical network terminal. A first optical signal from the optical fiber is transmitted to the optical module, and is converted by the optical module into a first electrical signal; said first electrical signal is transmitted to the optical network terminal. A second electrical signal from the optical network terminal is transmitted to the optical module, and is converted by the optical module into a second optical signal; said second optical signal is transmitted to the optical fiber. Since information can be transmitted between multiple information processing devices via electrical signals, only at least one of the multiple information processing devices is needed to be directly connected to the optical module, instead of all the information processing devices being directly connected to the optical module. Here, the information processing device directly connected to the optical module is referred to as a host computer of the optical module. In addition, the optical signal input port or the optical signal output port of the optical module may be referred to as an optical port, and the electrical signal input port or electrical signal output port of the optical module may be referred to as an electrical port.

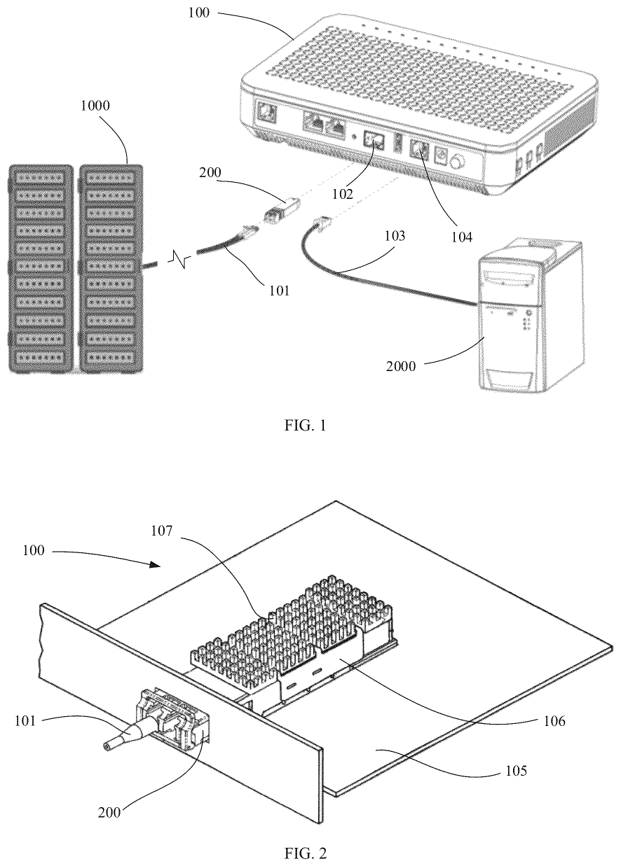

FIG. 1 is a part of a structural diagram of an optical communication system provided according to some embodiments of the present disclosure. As shown in FIG. 1, the optical communication system mainly includes a remote information processing device 1000, a local information processing device 2000, a host computer 100, an optical module 200, an optical fiber 101 and a network cable 103. In some embodiments, the remote information processing device may also be referred to as a remote server, and the host computer may also be referred to as an optical network terminal.

One end of the optical fiber 101 extends toward the remote information processing device 1000, and the other end of the optical fiber 101 is connected to the optical module 200 through the optical port of the optical module 200. Optical signals can be totally reflected in the optical fiber 101, and may propagate in the direction of total reflection substantially without power loss. An optical signal undergoes many times of total reflections in the optical fiber 101, so that the optical signal from the remote information processing device 1000 may be transmitted to the optical module 200, or the optical signal from the optical module 200 may be transmitted to the remote information processing device 1000, so as to realize an information transmission of long-distance and low power loss.

The optical communication system may include one or more optical fibers 101, and the optical fibers 101 are detachably or fixedly connected to the optical module 200. The host computer 100 is configured to provide data signals to the optical module 200, or receive data signals from the optical module 200, or monitor or control an operation of the optical module 200.

The host computer 100 includes a substantially rectangular parallelepiped housing, and an optical module interface 102 provided on the housing. The optical module interface 102 is configured to access the optical module 200, so that a uni-directional or bi-directional electrical connection between the host computer 100 and the optical module 200 is established.

The host computer 100 also includes an external electrical interface, which may access an electrical signal network. For example, the external electrical interface may include a Universal Serial Bus (USB) interface or a network cable interface 104; the network cable interface 104 is connected to the network cable 103, so that a uni-directional or bi-directional electrical connection is established between the host computer 100 and the network cable 103. One end of the network cable 103 is connected to the local information processing device 2000, and the other end of the network cable 103 is connected to the host computer 100, so as to establish an electrical connection between the local information processing device 2000 and the host computer 100 via the network cable 103. For example, a third electrical signal sent by the local information processing device 2000 is transmitted to the host computer 100 through the network cable 103, and the host computer 100 generates a second electrical signal according to the third electrical signal which is then transmitted to the optical module 200; the optical module 200 converts the second electrical signal into a second optical signal, and outputs the second optical signal to the optical fiber 101; the second optical signal is transmitted to the remote information processing device 1000 via the optical fiber 101. For example, a first optical signal from the remote information processing device 1000 propagates through the optical fiber 101, is transmitted via the optical fiber 101 to the optical module 200; the optical module 200 converts the first optical signal into a first electrical signal, and transmits the first electrical signal to the host computer 100, which generates a fourth electrical signal according to the first electrical signal and transmits the fourth electrical signal to the local information processing device 2000. It should be noted that the optical module is a device to realize mutual conversion between optical signals and electrical signals. During above conversion of the optical signals and electrical signals, the information carried thereby is not changed, rather, the way that the information is encoded/decoded can be changed.

In addition to the optical network terminal, the host computer 100 may also include an optical line terminal (Optical Line Terminal, OLT), an optical network device (Optical Network Terminal, ONT), or a data center server, etc.

FIG. 2 is a partial structural diagram of a host computer provided according to some embodiments of the present disclosure. In order to clearly show a connection relationship between the optical module 200 and the host computer 100, FIG. 2 merely illustrates a partial structure of the host computer 100 that is interrelated with the optical module 200. As shown in FIG. 2, the host computer 100 also includes a PCB 105 arranged in the housing, a cage 106 arranged on a surface of the PCB 105, a radiator 107 arranged on the cage 106, and electrical connectors arranged inside the cage 106. The electrical connector is configured to access an electrical port of the optical module 200; the radiator 107 has a protruding structure such as fins to increase a heat dissipation area.

The optical module 200 is inserted into the cage 106 of the host computer 100, and is fixed by the cage 106. The heat generated by the optical module 200 is conducted to the cage 106 and then diffused through the radiator 107. When the optical module 200 is inserted into the cage 106, the electrical port of the optical module 200 is connected to the electrical connector inside the cage 106, so that a bi-directional electrical connection is established between the optical module 200 and the host computer 100. In addition, the optical port of the optical module 200 is connected with the optical fiber 101, so that a bi-directional optical connection is established between the optical module 200 and the optical fiber 101.

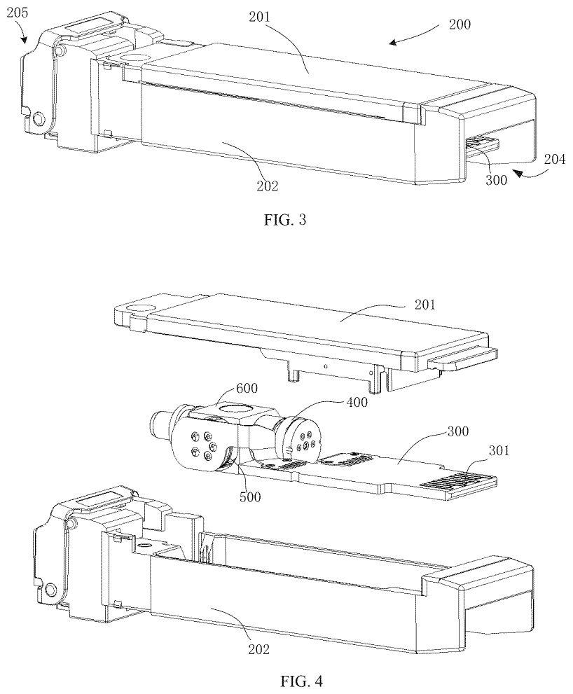

FIG. 3 is a schematic structural diagram of an optical module provided according to some embodiments of the present disclosure, and FIG. 4 is a schematic exploded structural diagram of an optical module provided according to some embodiments of the present disclosure. As shown in FIG. 3 and FIG. 4, the optical module 200 provided in some embodiments of the present disclosure includes a shell, a circuit board 300 disposed inside the shell, a round square waveguide 600, a light emitting component 400 and a light receiving component 500. But the present disclosure is not limited thereto, and in some embodiments, the optical module 200 may include one of the light emitting component 400 and the light receiving component 500.

The shell includes an upper shell 201 and a lower shell 202. The upper shell 201 is covered on the lower shell 202 to form the shell with two openings 204 and 205; the outer contour of the shell is generally in a cuboid shape.

In some embodiments, the lower shell 202 includes a bottom plate and two lower side plates respectively provided on two sides of the bottom plate perpendicularly to the bottom plate; the upper shell 201 includes a cover plate, and the cover plate is covered on two lower side plates of the lower shell 202 to form the above-mentioned shell.

In some embodiments, the lower shell 202 includes a bottom plate and two lower side plates respectively provided on two sides of the bottom plate perpendicularly to the bottom plate; the upper shell 202 includes a cover plate and two upper side plates respectively provided on two sides of the cover plate perpendicularly to the cover plate. The two upper side plates are respectively engaged with the two lower side plates, so that the upper shell is covered on the lower shell.

A virtual line connecting the two openings 204 and 205 may extend in a direction parallel to a length direction of the optical module 200, or may extend in a direction not parallel to the length direction of the optical module 200. For example, the opening 204 is provided at one end of the optical module 200 (the right end in FIG. 3), and the opening 205 is provided at the other end of the optical module 200 (the left end in FIG. 3). Alternatively, the opening 204 is provided at an end of the optical module 200, and the opening 205 is provided at a side of the optical module 200. The opening 204 forms an electrical port, and golden fingers 303 of the circuit board 300 may extend outwardly from the opening 204 and be inserted into an electrical connector of the host computer 100. The opening 205 forms an optical port and is configured to allow accessing of the external optical fiber 101, so that the optical fiber 101 may be connected to the light receiving component 400 and the optical transmission component 500 in the optical module 200. The circuit board 300, the round square waveguide 600, the light emitting component 400 and the light receiving component 500 and other opto-electronic devices are arranged in the enclosing cavity formed by the upper shell and lower shell.

The way in which the upper shell 201 cooperates with the lower shell 202 to form an assembly helps to arrange devices such as the circuit board 300, the light receiving component 400, and the light emitting component 500 into the shell. The upper shell 201 and the lower shell 202 form an outermost packaging protective enclosure for the above devices. In addition, during assembly of devices such as the circuit board 300, the light receiving component 400, and the light emitting component 500, an arrangement of positioning components, heat dissipation components, and electromagnetic shielding components for these devices may be facilitated, which is beneficial to automatic implementation and production.

In some embodiments, the upper shell 201 and the lower shell 202 are made of metal materials, which is beneficial to realize electromagnetic shielding and heat dissipation.

In some embodiments, the optical module 200 further includes an unlocking part arranged on the outer wall of its shell that is configured to realize a fixed connection between the optical module 200 and the host computer or to release the fixed connection between the optical module 200 and the host computer.

For example, the unlocking part 203 may be arranged on the outer walls of the two lower side plates of the lower shell 202, and includes a snap component matching with the cage 106 of the host computer 100. When the optical module 200 is inserted into the cage 106, the optical module 200 is fixed within the cage 106 by the snap component of the unlocking part 203; when the unlocking part 203 is pulled, the snap component of the unlocking part 203 moves therewith, such that the connection relationship between the snap component and the host computer is in turn changed in order to release the fixed engagement between the optical module 200 and the host computer; by this, the optical module 200 can be pulled out of the cage 106.

The circuit board 300 is provided with circuit tracings, electronic components and chips. The electronic components and chips are connected according to circuit design via circuit tracings, so as to realize functions such as power supply, electrical signal transmission and grounding. The electronic components may include, for example, capacitors, resistors, triodes, and Metal-Oxide-Semiconductor Field-Effect Transistor (MOSFET). The chip may include, for example, a Microcontroller Unit (MCU), a laser driver chip, a transimpedance amplifier (TIA), a limiting amplifier, a Clock and Data Recovery (CDR), a power management chip, and a Digital Signal Processing (DSP) chip.

The circuit board 300 is generally a rigid circuit board. Due to its relatively hard material, the rigid circuit board can also realize a carrying function, for example to carry the above electronic components and chips stably; the rigid circuit board can also be inserted into the electrical connector in the cage 106 of the host computer 100.

The circuit board 300 is also provided with golden fingers 303 formed on an end surface thereof, and the golden fingers 303 are formed of a plurality of pins independent of each other. The circuit board 300 is inserted into the cage 106, with the golden fingers 303 being conductively connected with the electrical connector in the cage 106. The golden fingers 303 may be only provided on one surface of the circuit board 300 (such as the upper surface shown in FIG. 4), or may also be provided on both the upper surface and the lower surface of the circuit board 300 for arranging more pins, so as to adapt to occasions in which a large number of pins are required. The golden fingers 303 are configured to establish an electrical connection with the host computer to realize power supply, grounding, inter-integrated circuit (I2C) signal transmission, data signal transmission, etc. Of course, flexible circuit boards may also be used in some optical modules. Flexible circuit boards are generally used in cooperation with the rigid circuit boards as a supplement to rigid circuit boards.

At least one of the light emitting component 400 or the light receiving component 500 is located on a side of the circuit board 300 that is away from the golden fingers 301.

In some embodiments, the light emitting component 400 and the light receiving component 500 are physically separated from the circuit board 300 respectively, and are electrically connected to the circuit board 300 via corresponding flexible circuit boards or electrical connectors respectively.

In some embodiments, at least one of the light emitting component or the light receiving component may be directly disposed on the circuit board 300. For example, at least one of the light emitting component or the light receiving component may be disposed on the surface of the circuit board 300 or on a side of the circuit board 300.

As shown in FIG. 4, in the optical module provided in this embodiment, the light emitting component 400 and the light receiving component 500 are arranged in the round square waveguide 600 together, wherein the light emitting component 400 is used for generating and outputting signal light, and the light receiving component 500 is used for receiving signal light from outside the optical module. A fiber optic adapter is arranged on the round square waveguide 600, and is used to realize a connection between the optical module and the external optical fiber. The round square waveguide 600 is usually provided with a lens assembly which is used for changing a propagation direction of the signal light output by the light emitting component 400 or the signal light input from the external optical fiber. Since the light emitting component 400 and the light receiving component 500 are physically separated from the circuit board 300, so it is difficult for the light emitting component 400 and the light receiving component 500 to be directly connected to the circuit board 300; thus, according to the present disclosure, the electrical connection for the light emitting component 400 and the light receiving component 500 is realized by flexible circuit boards respectively. In some embodiments of the present disclosure, an assembly configuration of the light emitting component 400 and the light receiving component 500 is not limited to the way shown in FIG. 3 and FIG. 4, and other configurations for assembly and combination are also possible; for example, the light emitting component 400 and the light receiving component 500 are arranged in different waveguides; this embodiment only takes the structure shown in FIG. 3 and FIG. 4 as an example.

Coupling of the light emitting component 400 and the light receiving component 500 via the round square waveguide 600 facilitates a control on the optical transmission path of the signal light on one hand, and facilitates a compact design inside the optical module and reduces a space occupied by the optical transmission path of the signal light on the other hand. In addition, with the development of wavelength division multiplexing technology, in some optical modules, more than one light emitting component 400 and light receiving component 500 are disposed in the round square waveguide 600.

In some embodiments of the present disclosure, a transflective mirror is also disposed in the round square waveguide 600, which is configured to change a propagation direction of the signal light to be received by the light receiving component 500 or to change a propagation direction of the signal light generated by the light emitting component 400, and is convenient for the light receiving component 500 to receive the signal light or for the light emitting component 400 to output signal light.

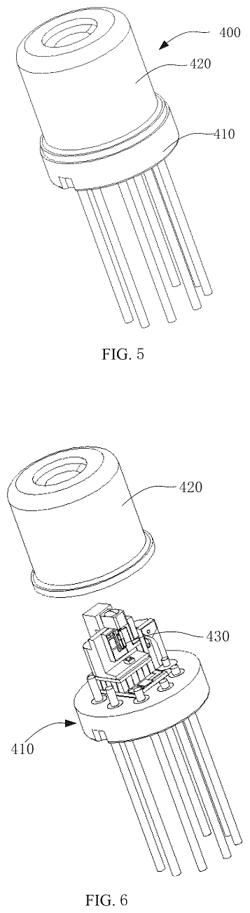

FIG. 5 is a structure outline diagram of a light emitting component provided according to some embodiments of the present disclosure. As shown in FIG. 5, the light emitting component 400 provided in this embodiment includes a tube base 410, a tube cap 420 and other devices arranged within the tube cap 420 and the tube base 410. The tube cap 420 is provided to cover one end of the tube base 410. Several pins are provided on the tube base 410, which are used to realize an electrical connection between the flexible circuit board and other electrical devices in the light emitting component 400, and thus to realize an electrical connection between the light emitting component 400 and the circuit board 300.

FIG. 6 is a schematic structural diagram of a light emitting component provided according to some embodiments of the present disclosure, in which a tube base and a tube cap of the light emitting component are separate from each other. As shown in FIG. 6, the light emitting component 400 includes a laser 430 for generating signal light, and the generated signal light passes through the tube cap 420.

The high-frequency modulation performance of the laser is jointly determined by a high-frequency response of an active region and a high-frequency response of a high-speed transmission structure. The high-speed transmission structure is crucial to a high-bandwidth performance/ultra-high-bandwidth performance, and has become a crucial technology barrier to the performance of high-speed optical communication. An optical module/optical device design with excellent high-speed performance will significantly improve the key performance and competitiveness of the product. Any impedance mismatch or resonance effect will seriously deteriorate the performance of the whole product, causing the device unable to be used in high-speed applications.

FIG. 7 is a schematic structural diagram of a laser in an optical module provided according to some embodiments of the present disclosure. As shown in FIG. 7, exemplarily, the laser 06 includes a laser chip 061 and a ceramic substrate 062, and the laser chip 061 is arranged on the surface of the ceramic substrate 062. In which, a circuit pattern is formed on the surface of the ceramic substrate 062, which may be used for supplying power to the laser chip 061 and transmitting signals; at the same time, the ceramic substrate 062 has a better thermal conductivity, and can be used as a radiator for the laser chip 061 to dissipate heat. Several electrodes are provided on the upper surface of the laser chip 061, and pads which are correspondingly connected to the surface circuit board of the laser chip 061 are provided on the ceramic substrate 062, and the electrodes on the upper surface of the laser chip 061 are connected to the corresponding pads by bonding wires.

The embodiment of the present application packages the laser by adopting a Chip On Chip (CoC) technology, that is, the laser chip is mounted onto a substrate such as a ceramic substrate, so that the laser chip is bonded to high-speed circuits and other circuits of the substrate via gold wires, so as to realize an interconnection between the laser chip and the ceramic substrate.

According to some embodiments of the present disclosure, a length of the bonding wire may be adjusted, for example be reduced, so as to reduce the equivalent inductance. Correspondingly, the insertion loss may be correspondingly reduced, thereby improving the high-frequency performance of the laser. Unlike wirings in digital circuits, for bonding wires, parameters and characteristics such as quantity, length, height, span, position of weld spots, etc., will have a serious impact on high-speed transmission characteristics thereof. Especially at the high speed of 25 Gbps and above, the parasitic inductance effect of the bonding wire is particularly obvious. The geometric parameters of the bonding wire affect its equivalent inductance, capacitance, and resistance, and correspondingly change the interconnection characteristics thereof.

As shown in FIG. 7, in the above example, the upper surface of the laser chip 061 is positioned above the upper surface of the ceramic substrate 062, so the gold wire extending from the pad of the laser chip 061 needs to cross a certain height to be bonded to the ceramic substrate 062, and a chopper used in bonding wire is likely to interfere with the laser chip 061, so a second weld spot bonded onto the ceramic substrate 062 will be spaced apart from the laser chip 061 by a certain distance; therefore, the length of the entire gold wire is unable to be controlled to be relatively short, which in turn results in a large parasitic inductance effect and deteriorates the high frequency performance of the laser.

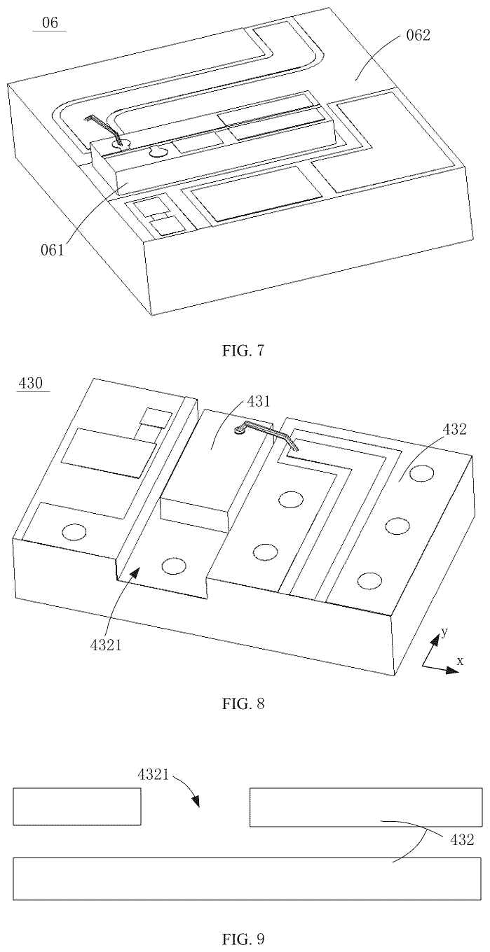

FIG. 8 is a schematic structural diagram of a laser provided according to some embodiments of the present disclosure. As shown in FIG. 8, in order to improve the high-frequency performance of the laser, in some examples, the laser 430 may include a laser chip 431 and a substrate 432. In which, the substrate 432 may include but not limited to a ceramic substrate, a glass substrate, a silicon substrate or an organic sheet substrate.

Circuits are laid on the upper surface of the substrate 432, and the laser chip 431 is connected to the corresponding circuits on the substrate 432 via bonding wires; the electrodes on the upper surface of the laser chip 431 are connected to the pads on the substrate 432 via bonding wires correspondingly.

In order that the length of the bonding wires between the laser chip 431 and the substrate 432 may be controlled to be relatively short, a chip mounting groove 4321 is formed in the substrate 432, with the depth of the chip mounting groove 4321 being close to or equal to the thickness of the laser chip 431; the laser chip 431 is mounted/bonded in the chip mounting groove 4321, so that the pad on the laser chip 431 is approximately at the same level with the circuit trace on the substrate 432; at the same time, the width of the chip mounting groove 4321 is controlled (to ensure that, at one hand, the laser chip 431 is well accommodated, and at the other hand there is no much free space remaining after the laser chip 431 is fitted into the groove), so that the bonding wire may have a reduced height, and there is no problem of chopper interference; the length of the gold wire may be controlled to be relatively short, that is, the length of the bonding wire is shortened to reduce the equivalent inductance, and accordingly, the insertion loss may also be reduced, thereby improving the high-frequency performance of the laser.

In some embodiments of the present disclosure, the chip mounting groove 4321 may be designed as a chip mounting groove in the form of a blind hole, or may be a chip mounting groove that extends across the entire width or length of the substrate 432. Referring to FIG. 8, the length direction of the substrate 432 is illustrated to be in the x direction, and the width direction thereof is illustrated to be in the y direction.

Exemplarily, as shown in FIG. 8, the chip mounting groove 4321 runs through two sidewalls of the substrate 432 opposite to each other in the width direction. When a laser chip 431 is to be assembled and fixed, the laser chip 431 is clamped and oriented in a direction parallel to the width of the substrate 432, so that an assembly and fixing of the laser chip 431 may be facilitated.

Taking a case where the chip mounting groove 4321 runs through the two sidewalls of the substrate 432 opposite to each other in the width direction as an example, currently, two methods can be used to process and prepare a substrate 432 with chip mounting groove 4321. According to method 1, two pieces of ceramic green body to be provided on the topmost layer are selected according to the required depth of the chip mounting groove 4321, that is, the thickness of the ceramic green body is chosen to be equal to the depth of the chip mounting groove 4321, and the two ceramic green bodies are aligned in accordance with the width of the chip mounting groove 4321, so that the distance between the two pieces of ceramic green bodies is equal to the width of the chip mounting groove 4321; the ceramic green bodies is then sintered under high temperature. According to method 2, a chip mounting groove 4321 is etched directly on the sintered substrate 432 in accordance with the size requirements of the chip mounting groove 4321.

FIG. 9 is a schematic structural diagram of a ceramic substrate provided according to some embodiments of the present disclosure. The ceramic substrate is processed and prepared according to the method 1. According to this preparation method, the two pieces of ceramic green bodies provided on the topmost layer need to be formed with the ceramic green body below integrally via high-temperature sintering; however, a high-temperature sintering process cannot guarantee an accurate dimension of the formed body, which will thus lead to a variation in size of the chip mounting groove 4321 obtained by sintering process, and precision requirements of the chip mounting groove 4321 cannot be met.

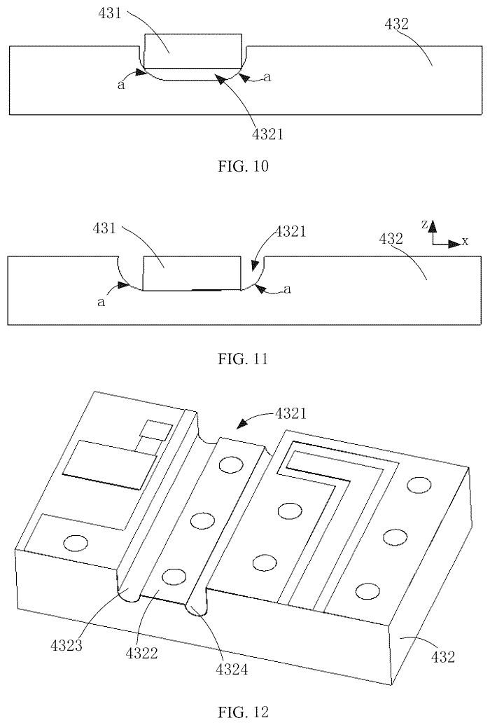

FIG. 10 is a schematic structural diagram of another ceramic substrate provided according to some embodiments of the present disclosure. This ceramic substrate is processed and prepared according to the method 2. In this preparation method, the sintered substrate 432 is directly etched in accordance with the size of the chip mounting groove 4321, but due to the characteristics of the etching process, rounded corners are formed at two bottom edges of the chip mounting groove 4321 by etching process (for example a first rounded corner, referring to the corner a in FIG. 10), wherein a radius of the first rounded corner is greater than or equal to the thickness of the laser chip 431; for example, the radius of the first rounded corner is at least 0.1 mm; as a result, the laser chip 431 will get stuck as it is mounted into the groove, such that the laser chip 431 cannot be mounted correctly. In this context, the thickness of the laser chip 431 refers to a distance between two sides of the laser chip 431 facing away from each other in the z direction (referring to FIG. 11).

It is to be noted that, a surface shape of the first rounded corner corresponds to a surface shape of a grind head of a grinding device employed in the etching process of FIG. 10.

FIG. 11 is a schematic structural diagram of further ceramic substrate provided according to some embodiments of the present disclosure, which is also prepared based on the processing method 2. Compared with the chip mounting groove 4321 of the ceramic substrate shown in FIG. 10, the width of the chip mounting groove 4321 in FIG. 11 is increased. For example, the distance between the left rounded corner a and the right rounded corner a is greater than the width of the laser chip 431. In this way, although the stucking problem associated with the chip mounting groove shown in FIG. 10 can be solved by increasing the width of the groove body of the chip mounting groove 4321, the length of the bonding wire will be accordingly increased, thereby deteriorating the high frequency performance of the laser 430. In this context, a width of the laser chip 431 refers to the distance between two opposite side walls of the laser chip 431 facing away from each other in the x direction.

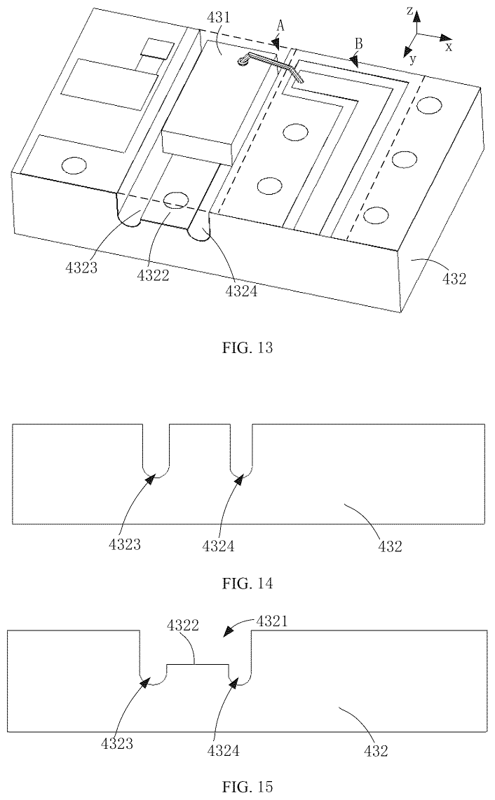

FIG. 12 is a schematic structural diagram of still another ceramic substrate provided according to some embodiments of the present disclosure, and FIG. 13 is a schematic structural view after a laser chip is assembled on the ceramic substrate of FIG. 12. As shown in FIGS. 12 and 13, a chip mounting groove 4321 is arranged on the substrate 432 provided in the embodiment of the present disclosure, with a chip carrying surface 4322 being formed at the bottom of the chip mounting groove 4321; a deepening groove is formed in at least part of the sides of the chip carrying surface 4322. The height difference between the bottom surface of the deepening groove and the top surface of the substrate 432 is greater than the height difference between the chip carrying surface 4322 and the top surface of the substrate 432, that is, the depth of the deepening groove is greater than the depth of the chip carrying surface 4322, and the laser chip 431 is arranged on the chip carrying surface 4322. The deepening groove is designed for keeping out of the way of the corners of the laser chip 431, avoiding occurrence of the stucking problem and facilitating a mounting of the laser chip 431; at the same time, the bonding wire length between the laser chip 431 and the substrate 432 can be controlled within a short range without increasing the width of the chip mounting groove 4321.

In some examples, when the chip mounting groove 4321 is designed to have a blind hole configuration provided on the substrate 432, that is, when the four inner walls of the chip mounting groove 4321 are all spaced apart from respective side wall of the substrate 432 by a certain distance, a chip carrying surface 4322 and at least one deepening groove will be formed at the bottom of the chip carrying surface 4322, and the at least one deepening groove is provided on at least one side of the chip carrying surface 4322.

For example, there may be four deepening grooves, and the four deepening grooves are respectively arranged around the chip carrying surface 4322 to keep out of the way of the four corners the laser chip 431, so as to avoid the stucking problem. For another example, there may be two deepening grooves, and the two deepening grooves are respectively arranged on two sides of the chip carrying surface 4322; for example, they may be respectively arranged on opposite sides of the chip carrying surface 4322 in the length direction of the substrate 432, in order to keep out of the way of the corners on both sides of the laser chip 431 opposite to each other in the length direction, so as to avoid the stucking problem.

In some other examples, when the chip mounting groove 4321 is of a groove structure that extends through the entire width of the substrate 432, deepening grooves may be disposed on opposite sides of the chip carrying surface 4322 along the length direction of the substrate 432; for example, the deepening grooves can be provided on both sides of the chip-carrying surface 4322 opposite to each other in the length direction of the substrate 432 to keep out of the way of the corners on both sides of the laser chip 431 opposite to each other in the length direction, to as to avoid the stucking problem.

Referring to FIG. 12, specifically, the deepening grooves may include a first deepening groove 4323 and a second deepening groove 4324; the chip carrying surface 4322 extends in the length direction of the chip mounting groove 4321, with the first deepening groove 4323 being located on one side of the chip carrying surface 4322 in the length direction, and the second deepening groove 4324 being located on the other side of the chip carrying surface 4322 in the length direction.

The height difference between the bottom surface of the first deepening groove 4323 and the top surface of the substrate 432 is greater than the height difference between the chip carrying surface 4322 and the top surface of the substrate 432, and the height difference between the bottom surface of the second deepening groove 4324 and the top surface of the substrate 432 is greater than the height difference between the chip carrying surface 4322 and the top surface of the substrate 432; that is, in the chip mounting groove 4321, both the depth at the first deepening groove 4323 and the depth at the second deepening groove 4324 are greater than the depth at the chip carrying surface 4322; the laser chip 431 is arranged on the chip carrying surface 4322. Due to the arrangement of the first deepening groove 4323 and the second deepening groove 4324, it is possible to keep out of the way of the corners of the laser chip 431, so as to avoid the stucking problem and facilitate a mounting of the laser chip 431; at the same time, the bonding wire length between the laser chip 431 and the substrate 432 can be controlled within a short range without increasing the width of the chip mounting groove 4321.

In some other possible embodiments, at the bottom of the chip mounting groove 4321 there may be only provided with the chip carrying surface 4322 and the first deepening groove 4323, or at the bottom of the chip mounting groove 4321 there may be only provided with the chip carrying surface 4322 and the second deepening groove 4324, and the purpose of being kept out of the way of the corner of the laser chip 431 is realized by controlling the width of the first deepening groove 4323 or the second deepening groove 4324. In some embodiments of the present disclosure, the height difference between the chip carrying surface 4322 and the top surface of the substrate 432 is equal to or approximate to the thickness of the laser chip 431; exemplarily, a difference between the height difference between the chip carrying surface 4322 and the top surface of the substrate 432 and the thickness of the laser chip 431 is within ±10 μm.

In FIGS. 12 and 13, the chip mounting groove 4321 penetrates through the substrate 432, and the chip carrying surface 4322 extends to both sides of the substrate 432; but the present disclosure is not limited to those shown in FIGS. 12 and 13. For example, the chip mounting groove 4321 may not penetrate through the substrate 432, and the chip carrying surface 4322 may not extend to the side of the substrate 432.

In some embodiments of the present disclosure, the depths and widths of the first deepening groove 4323 and the second deepening groove 4324 can generally be selected based on the formed rounded corners (for example the second rounded corner). The depths of the first deepening groove 4323 and the second deepening groove 4324 is greater than the radius of the second rounded corners, and the widths of the first deepening groove 4323 and the second deepening groove 4324 is greater than the diameter of the second rounded corner. Among which, a surface shape of the second rounded corner corresponds to a surface shape of a grind head of a grinding device employed in the etching process of FIG. 12 and FIG. 13.

It should be noted that the depth of the first deepening groove 4323 refers to the vertical distance between the bottom surface of the first deepening groove 4323 and the top surface of the substrate 432; exemplarily, this vertical distance is greater than the radius of the second rounded corner a. Similarly, the depth of the second deepening groove 4324 refers to the vertical distance between the bottom surface of the second deepening groove 4324 and the top surface of the substrate 432, and exemplarily, said vertical distance is greater than the radius of the second rounded corner a.

In certain examples, the depth of the first deepening groove 4323 is greater than the thickness of the laser chip 431. In addition, the depth of the second deepening groove 4324 is greater than the thickness of the laser chip 431.

In addition, the width between the first deepening groove 4323 and the second deepening groove 4324 may be greater than the diameter of the second rounded corner a. It is to be understood that the width between the first deepening groove 4323 and the second deepening groove 4324 refers to the width between the left side of the first deepening groove 4323 and the right side of the second deepening groove 4324 (the width is in the x direction in FIG. 13).

Exemplarily, the width between the first deepening groove 4323 and the second deepening groove 4324 may be greater than or equal to the width of the laser chip 431.

The chip mounting grooves 4321 shown in FIGS. 12 and 13 can be directly formed by etching. FIG. 14 is a schematic structural view of a ceramic substrate according to some embodiments of the present disclosure, with a chip mounting groove having been machined on the ceramic substrate; FIG. 15 is a schematic structural view of another ceramic substrate according to some embodiments of the present disclosure, with a chip mounting groove having been machined on the ceramic substrate. As shown in FIGS. 14 and 15, the side edges of the chip mounting groove 4321 are first etched according to the size of the chip mounting groove 4321, and the first deepening groove 4323 and the second deepening groove 4324 are etched at the bottom of the side edges, then the middle section located between the first deepening groove 4323 and the second deepening groove 4324 is etched to from the chip carrying surface 4322, wherein both the depth of the first deepening groove 4323 and the depth of the second deepening groove 4324 are greater than the depth of the chip carrying surface 4322. In this way, a chip mounting groove 4321 shown in FIGS. 12 and 13 is obtained, which can effectively avoid the problem that a mounting of the laser chip 431 is adversely affected by the rounded corners formed at the bottom on both sides during the etching process for forming the chip mounting groove 4321, and at the same time can effectively avoid an increase of the width of the chip mounting groove 4321, which is beneficial for controlling a bonding wire length between the laser chip 431 and the substrate 432 within a relatively short range, ensuring the high frequency performance of the laser.

In some embodiments of the present disclosure, the substrate 432 is a multi-layer board, that is, the substrate 432 includes at least two layers of ceramic green bodies. If it is necessary to lay circuits on each layer of the ceramic green body, they can be manufactured/formed on the ceramic green body via printing or other methods, and then all layers of green body are aligned before being sintered at a high temperature; usually, a sintering temperature is above 1000 degrees Celsius. Finally, after surface polishing, the circuits are fabricated on the ceramic surface via metal sputtering or evaporation processes.

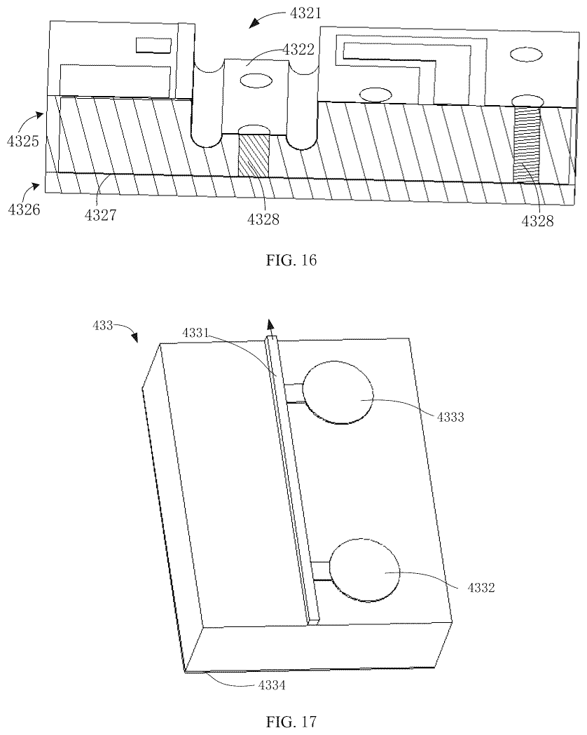

In some embodiments of the present disclosure, the chip carrying surface 4322 may be located at the center of the chip mounting groove 4321. The height difference between the bottom surface of the first deepening groove 4323 and the top surface of the substrate 432 may be equal to or may not be equal to the height difference between the bottom surface of the second deepening groove 4324 and the top surface of the substrate 432. FIG. 16 is a cross-sectional view of a ceramic substrate provided according to some embodiments of the present disclosure. The substrate 432 shown in FIG. 16 is a double-layered ceramic substrate. As shown in FIG. 16, the substrate 432 in this embodiment includes a top board 4325 and a bottom board 4326 that are formed by high temperature sintering, and the chip mounting groove 4321 is formed in the top board 4325.

In some embodiments of the present disclosure, the size of the substrate 432 is relatively small. In order to meet the requirements of the laser chip 431 for circuits, not only circuits are laid on the top surface of the substrate 432, but also a circuit layer 4327 needs to be disposed inside the substrate 432, with circuits being formed on the circuit layer 4327. Therefore, as shown in FIG. 16, a first circuit is laid on the upper surface of the top board 4325, a first extended circuit is laid on the lower surface of the top board 4325, via holes 4328 (such as a first via hole) are provided within the top board 4325, such that the first circuit is connected to the first extended circuit through the via holes 4328. A lay-out of the first circuit and the first extended circuit can be selected as needed, and thus positions and quantity of the via the holes 4328 can be selected according to the first circuit and the first extended circuit, and there is not particular limitation in the embodiment of the present disclosure.

Exemplarily, one portion of the first circuit may be laid on the surface outside the chip mounting groove 4321 on the top board 4325, and the other portion of the first circuit may be laid on the inner bottom wall of the chip mounting groove 4321, for example, the other portion of the first circuit is laid on the chip carrying surface 4322.

Correspondingly, some via holes 4328 disposed in the top board 4325 is arranged offset with respect to the chip mounting groove 4321 in a direction perpendicular to the thickness of the substrate 432, with one end of these via hole 4328 being electrically connected to the first circuit on the outer surface of the chip mounting groove 4321; and for the other via holes 4328, the projections thereof on the top surface of the substrate 432 fall onto the chip carrying surface 4322, that is, the other via holes 4328 are located directly below the chip mounting groove 4321, with one end thereof being communicated with the chip carrying surface 4322 so as to be electrically connected to the first circuit on the chip carrying surface 4322. In this way, a length of an electrical connection path between the elements at the bottom of the laser chip 432 and the first extension circuit can be reduced, so as to reduce line loss and thereby improve the high frequency performance of the laser.

Exemplarily, a negative electrode of a laser chip and the like are disposed on the bottom surface of the laser chip 431, which need to be connected to circuits such as a ground circuit on the ceramic substrate. Therefore, in some embodiments of the present disclosure, a metal layer is disposed on the chip carrying surface 4322, and the bottom surface of the laser chip 431 is electrically connected to said metal layer, such that the laser chip 431 is grounded via the metal layer. Exemplarily, the bottom surface of the laser chip 431 is fixed on the chip carrying surface 4322 by solder, conductive silver glue, etc.; when an excessive amount of the solder, conductive silver glue, etc. is applied, the excessive solder, conductive silver glue, etc. may flow into the first deepening groove 4323 and the second deepening groove 4324, so as to prevent them from rising up along the side of the laser chip 431 and contaminating the side of the laser chip 431, further ensuring that the laser chip 431 is reliably fixed.

It should be noted that the laser chip is used to generate laser light according to the received high-speed signal, such as a distributed feedback semiconductor laser (DFB) chip. In order to solve the problem that the DFB semiconductor lasers cannot meet higher speed requirements due to the severe constraints of material differential gain and carrier lifetime, in some embodiments of the present disclosure, the laser chip can be a single laser chip which can include two positive electrodes, for example, the single laser chip may be an electro-absorption modulated laser chip (EML). It is to be understood that an electro-absorption modulation laser chip is an integrated chip of an electro absorption modulator (EAM) chip and a distributed feedback semiconductor laser (DFB) chip, that is, the electro-absorption modulation laser chip includes a light zone and an electro-absorption modulation zone.

It is to be understood that both the light emitting zone and the electro-absorption modulation zone have positive electrodes and negative electrodes, and the positive electrodes and negative electrodes are both electrically connected to a bias circuit which provides a bias current for the light emitting zone, so that light without data is emitted under the action of the bias current; the bias circuit further provides a bias voltage for the electro-absorption modulation zone, so that the electro-absorption modulation zone modulates the light emitted by the light emitting zone under the action of the bias voltage. The EML laser chip can modulate signals with higher rate requirements.

For another example, the laser chip can be a dual laser chip, that is, two positive electrodes are disposed on the top surface of the laser chip, and the two positive electrodes are electrically connected to a ridge waveguide, respectively, to form a dual laser structure (that is, a dual laser chip); then two high-frequency signals with time delay difference are received by the two positive electrodes correspondingly, such that a compensation for a bandwidth curve of the laser chip at a higher frequency is realized, so as to further improve the bandwidth and transmission rate and achieve higher rate modulation.

Exemplarily, the dual laser chip includes two light emitting units (also known as light emitting chips), and when the high-speed signals fed by the two light emitting units have a preset time delay difference, the optical signals generated by the light emitting units can be superimposed. For example, the dual laser chip may adopt a structure where a common waveguide is shared by two lasers.

FIG. 17 is a schematic structural diagram of a dual laser chip provided according to some embodiments of the present disclosure. As shown in FIG. 17, specifically, the laser provided in some embodiments of the present disclosure includes a dual laser chip 433 which includes a ridge waveguide 4331, a first positive electrode 4332 and a second positive electrode 4333 disposed on the top surface of the dual laser chip 433, and a negative electrode 4334 disposed on the bottom surface of the dual laser chip 433; wherein the first positive electrode 4332 and the second positive electrode 4333 are electrically connected to the ridge waveguide 4331, and high-frequency electrical signals can be fed into the ridge waveguide 4331 by the first positive electrode 4332 and the second positive electrode 4333.

In some embodiments of the present disclosure, when high-frequency electrical signals are fed into the ridge waveguide 4331 via the first positive electrode 4332 and the second positive electrode 4333, the high-speed modulated light generated by the single laser in the dual laser structure emits through the end surface of the ridge waveguide 4331 in the upper part shown in FIG. 17, as shown by the arrow in FIG. 17.

In some embodiments of the present disclosure, two high-speed electrical signals with a preset delay difference are fed into the ridge waveguide 4331 by the first positive electrode 4332 and the second positive electrode 4333. Exemplarily, by adjusting the length of the RF wirings for feeding the two high-speed signals respectively, the two signals may have a preset time delay difference. However, due to the small area of the dual laser chip 433, there is not enough space for rewiring of the dual RF wires.

In order to meet the requirement of feeding two high-speed electrical signals with a preset delay difference by the dual laser chip 433, in some embodiments of the present disclosure, the laser further includes a substrate on which a first high-speed signal line, a second high-speed signal line and a first ground for backflow are disposed; the first positive electrode 4332 is electrically connected to the first high-speed signal line, the second positive electrode 4333 is electrically connected to the second high-speed signal line, and the negative electrode 4334 is electrically connected to the first ground for backflow; a combination of the first high-speed signal line and the second high-speed signal line realizes a feeding of two high-speed electrical signals with a preset delay difference into the dual laser chip 433. In some embodiments of the present disclosure, the positions and orientations of the first high-speed signal line and the second high-speed signal line are set in consideration of the size of the substrate and the requirements of the dual laser chip 433. Exemplarily, the length of the second high-speed signal line is greater than the length of the first high-speed signal line, or the length of the first high-speed signal line is greater than the length of the second high-speed signal line, so as to generate a preset delay difference. In some embodiments of the present disclosure, the preset time delay difference can be obtained through comprehensive calculation of a digital analog simulation combined with laser rate equations and of laser active zone design.

Exemplarily, the first high-speed signal line, the second high-speed signal line and the first return flow are arranged on the surface of the substrate.

In some embodiments of the present disclosure, the first positive electrode 4332 and the second positive electrode 4333 of the dual laser chip 433 are correspondingly connected to the first high-speed signal line and the second high-speed signal line via bonding wires, that is, the first positive electrode 4332 and the second positive electrode 4333 may be correspondingly connected to the first high-speed signal line and the second high-speed signal line by means of bonding wires. The negative electrode 4334 of the dual laser chip 433 is soldered to the first ground for backflow.

In some embodiments of the present disclosure, the first positive electrode 4332 and the second positive electrode 4333 of the dual laser chip 433 can be correspondingly connected to the first high-speed signal line and the second high-speed signal line by flip-chip welding, and the negative electrode 4334 of the dual laser chip 433 is connected to the first ground for backflow by bonding wires, that is, the negative electrode 4334 is connected to the first ground for backflow by bonding wires. Exemplarily, the negative electrode 4334 of the dual laser chip 433 is connected to the first ground for backflow via a plurality of bonding wires.

In some embodiments of the present disclosure, in order to make use of the space on the substrate reasonably and arrange the high-speed signal lines reasonably, the dual laser chip 433 is arranged to be located close to an end of the substrate, that is, one end of the first high-speed signal line and one end of the second high-speed signal line are close to said end of the substrate for electrically connecting to the first positive electrode 4332 and the second positive electrode 4333; the other end of the first high-speed signal line and the other end of the second high-speed signal line are close to the other end of the substrate, so that the first high-speed signal line and the second high-speed signal line may extend from one end of the substrate to the other end of the substrate.

In some embodiments of the present disclosure, a first matching circuit is disposed on the first high-speed signal line, and a second matching circuit is disposed on the second high-speed signal line; the first matching circuit is arranged on the first high-speed signal line at a position close to the first positive electrode 4332, and the first matching circuit is used to realize an impedance matching between the dual laser chip 433 and the first high-speed signal line; the second matching circuit is arranged on the second high-speed signal line at a position close to the second positive electrode 4333, and the second matching circuit is used to realize impedance matching between the dual laser chip 433 and the second high-speed signal line. The first matching circuit and the second matching circuit may include resistors, or a combination of resistors and capacitors. Exemplarily, both the first matching circuit and the second matching circuit include thin-film resistors, with a first thin-film resistor being disposed in series on the first high-speed signal line and close to the first positive electrode 4332, and a second thin-film resistor being disposed in series on the second high-speed signal line and close to the second positive electrode 4333.

In some embodiments of the present disclosure, the first high-speed signal line is a straight high-speed signal line, and the second high-speed signal line is a bended high-speed signal line, wherein the degree of bending may be selected and changed according to the first high-speed signal line and the preset delay difference between the high-speed signals transmitted on the first high-speed signal line and the second high-speed signal line.

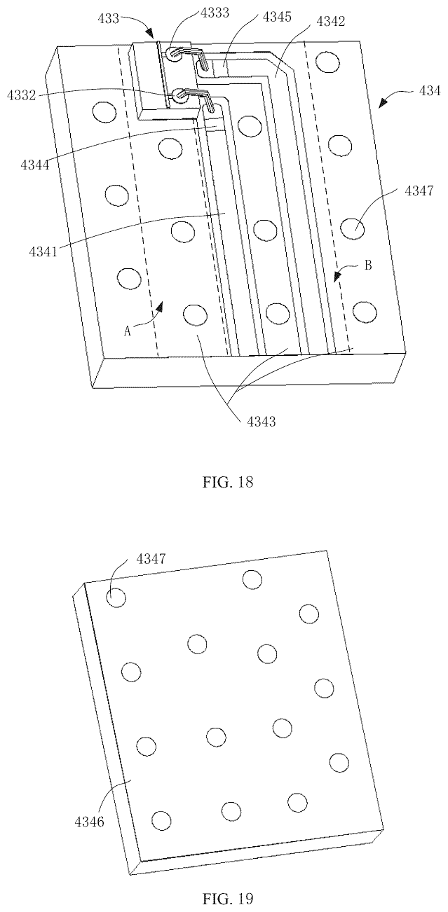

FIG. 18 is a schematic structural diagram of a top surface of a laser provided according to some embodiments of the present disclosure. As shown in FIG. 18, specifically, the laser includes a dual laser chip 433 and a substrate 434 (such as a ceramic substrate), wherein the dual laser chip 433 is disposed on the substrate 434, and the bottom surface of the dual laser chip 433 is connected to the top surface of the substrate 434. A first high-speed signal line 4341, a second high-speed signal line 4342 and a first ground for backflow 4343 are disposed on the top surface of the substrate 434. The first positive electrode 4332 is wire bonded to the first high-speed signal line 4341, the second positive electrode 4333 is wire bonded to the second high-speed signal line 4342, and the negative electrode 4334 is connected to the first ground for backflow 4343 by means of soldering.

In some embodiments of the present disclosure, a chip mounting groove (not shown in FIG. 18) may be provided in a recessed way within the substrate 434, so that the dual laser chip 433 is mounted in the chip mounting groove, and the depth of the chip mounting groove is approximate to or equal to the thickness of the dual laser chip 433, such that chip pads on the dual laser chip 433 are approximately at the same level with the upper surface of the substrate 434. At the same time, the width of the chip mounting groove may be controlled (not only to ensure an accommodation of the laser chip, but also not to have too much free space after the laser chip is accommodated), so that the height of the bonding wires may be minimized. By this, there is no problems caused by chopper interference, and the length of the gold wire is also within a short range, thereby further improving the high-frequency performance of the laser.

At this time, the first positive electrode 4332 and the second positive electrode 4333 of the dual laser chip 433 are correspondingly connected to the first high-speed signal line and the second high-speed signal line by bonding wires, that is, the first positive electrode 4332 and the second positive electrode 4333 may be correspondingly connected to the first high-speed signal line and the second high-speed signal line via bonding wires; a metal layer is disposed on the chip carrying surface of the chip mounting groove, and the negative electrode 4334 on the bottom surface of the double laser chip 433 is electrically connected to the metal layer; the double laser chip 433 is connected to ground through said metal layer.

It is to be understood that, in FIG. 18, area A can be used for providing a chip mounting groove, and area B (referring to FIG. 13 and FIG. 18) may be used for arranging the first high-speed signal line 4341 and the second high-speed signal line 4342.

In this embodiment, the length of the second high-speed signal line 4342 is greater than that of the first high-speed signal line 4341, so as to feed high-speed signals with a preset delay difference into the ridge waveguide 4331.

In this embodiment, the first high-speed signal line 4341 and the second high-speed signal line 4342 extend from one end of the substrate 434 to the other end of the substrate; exemplarily, one end of the first high-speed signal line 4341 is close to one end of the substrate 434, and the other end of the first high-speed signal line 4341 extends to the other end of the substrate 434. One end of the second high-speed signal line 4342 is located at one end of the substrate 434, and the other end of the second high-speed signal line 4342 extends to the other end of the substrate 434.

In order to effectively control the bonding wire length between the first positive electrode 4332 and the first high-speed signal line 4341 as well as the bonding wire length between the second positive electrode 4333 and the second high-speed signal line 4342, the dual laser chip 433 is arranged at one end of the substrate 434.

In some embodiments of the present disclosure, the first high-speed signal line 4341 is a straight high-speed signal line, and the second high-speed signal line 4342 is a bended high-speed signal line; one end of the second high-speed signal line 4342 is perpendicular to the first high-speed signal line 4341, and the other end of the second signal line 4342 is parallel to the first high-speed signal line 4341, that is, from the bending region of the second high-speed signal line 4342 to its other end, the second high-speed signal line 4342 extends in a way parallel to the first high-speed signal line 4341, so that it is convenient for the other ends of the high-speed signal line 4341 and the second high-speed signal line 4342 to be connected to a signal input circuit. In some embodiments of the present disclosure, the second high-speed signal line 4342 has one bending region, but is not limited thereto.

According to the embodiment of the present application, for the substrate 434 with a limited size, a second high-speed signal line 4342 with bending configuration is disposed on its top surface, so that a length of the second high-speed signal line 4342 may be extended, and the length difference between the second high-speed signal line 4342 and the first high-speed signal line 4342 may be increasing, such that high-speed signals with a preset delay difference may be fed by the first high-speed signal line 4341 and the second high-speed signal line 4342 into the ridge waveguide 4331.

As shown in FIG. 18, the first high-speed signal line 4341 and the first positive electrode 4332 is connected in series with the first thin film resistor 4344 via bonding wires, and the second high-speed signal line 4342 and the second positive electrode 4332 is connected in series to with second thin film resistor 4345 via bonding wires.

As shown in FIG. 18, the first ground for backflow 4343 on the top surface of the substrate 434 is arranged around the first high-speed signal line 4341 and the second high-speed signal line 4342, and thus the first high-speed signal line 4341 and the second high-speed signal line 4342 are separated by means of the first ground for backflow 4343. FIG. 19 is a schematic structural diagram of a bottom surface of a laser provided according to some embodiments of the present disclosure, which is a view of FIG. 18 from another direction, showing the bottom surface of the laser illustrated in FIG. 18. In some embodiments of the present disclosure, as shown in FIG. 19, a second ground for backflow 4346 is further provided on the bottom surface of the substrate 434, and several via holes 4347, such as second via holes, are further provided on the substrate 434. The first ground for backflow 4343 on the top surface of the substrate 434 is electrically connected to the second ground for backflow 4346 on the bottom surface of the substrate 434 through the via holes 4347.

In this way, the second ground for backflow 4346 on the bottom surface of the substrate 434 may increase the area of the ground for backflow on the substrate 434, and can also be electrically connected with the first ground for backflow 4343 on the top surface of the substrate 434. Exemplarily, the via holes 4347 are evenly distributed on the first ground for backflow 4343.

In other examples, a third ground for backflow may also be disposed on the circumferential side walls of the substrate 434, and the two ends of the third ground for backflow in the height direction of the substrate 434 are respectively electrically connected to the first ground for backflow 4343 and the second ground for backflow 4346, so as to further increase the area of the ground for backflows of the substrate 434.

It should be noted that the circumferential side walls of the substrate 434 are to be understood as side walls arranged around the axis of the substrate 434 (such as the four side walls in FIG. 19), which are located between the top surface and the bottom surface of the substrate 434.

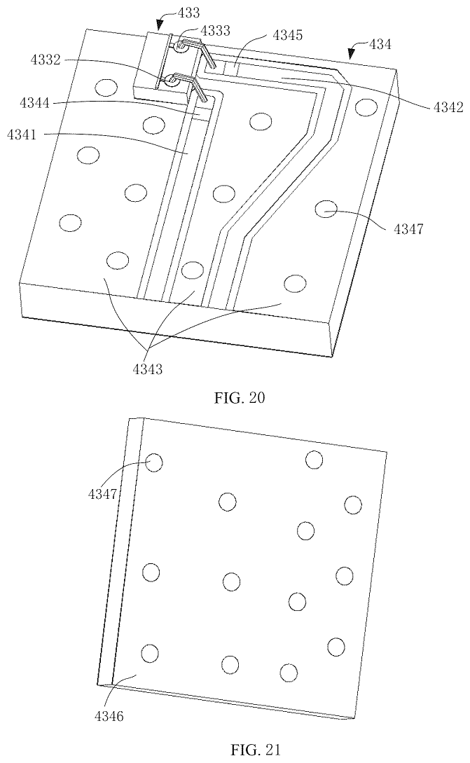

FIG. 20 is a schematic structural diagram of a top surface of another laser provided according to some embodiments of the present disclosure. As shown in FIG. 20, similar to the laser shown in FIG. 18, the laser in FIG. 20 includes a dual laser chip 433 and a substrate 434, the dual laser chip 433 is arranged on the substrate 434, and the bottom surface of the dual laser chip 433 is connected to the top surface of the substrate 434. The difference from the laser shown in FIG. 18 is that the second high-speed signal line 4342 is a bending high-speed signal line with three bends.

As shown in FIG. 20, one end (such as a first portion) of the second high-speed signal line 4342 is perpendicular to the first high-speed signal line 4341, a portion near the other end (such as a second portion) is parallel to the first high-speed signal line 4341, and the middle portion includes a plurality of bends; in the middle portion, there is a line section parallel to the first high-speed signal line 4341. Of course, in the embodiment of the present disclosure, there may not be a line section parallel to the first high-speed signal line 4341.

In this example, by designing the second high-speed signal line 4342 as a bending high-speed signal line with three bends, the extension length of the second high-speed signal line 4342 may increase with a limited-sized (such as a limited width size) top surface of the substrate 434, so as to increase the length difference between the second high-speed signal line 4342 and the first high-speed signal line 4341, thereby ensuring that a high-speed signal with a preset delay difference may be fed into the ridge waveguide 4331.

In addition, as shown in FIG. 20, in some examples, the distance between at least a section of the middle portion of the second high-speed signal line 4342 and the first high-speed signal line 4341 gradually increases in the direction from the second portion to the first portion. In this way, besides an increase of the extension length of the second high-speed signal line 4342, it is also possible to increase a distance between the second high-speed signal line 4342 and the first high-speed signal line 4341, thereby reducing signal interference between the second high-speed signal line 4342 and the first high-speed signal line 4341.

As shown in FIG. 20, the first ground for backflow 4343 on the top surface of the substrate 434 is arranged around the first high-speed signal line 4341 and the second high-speed signal line 4342. FIG. 21 is a schematic structural diagram of the bottom surface of another laser provided according to some embodiments of the present disclosure, which is a view of FIG. 20 from another direction, showing the bottom surface of the laser shown in FIG. 20. In some embodiments of the present disclosure, as shown in FIG. 21, a second ground for backflow 4346 is further disposed on the bottom surface of the substrate 434, and a plurality of via holes 4347 (such as second via holes) is further disposed on the substrate 434, with the first ground for backflow 4343 on the top surface of the substrate 434 being electrically connected to the second ground for backflow 4346 on the bottom surface of the substrate 434 through the via holes 4347. In this way, the second ground for backflow 4346 on the bottom surface of the substrate 434 can increase an area of the first ground for backflow on the substrate 434, and can also be electrically connected with the first ground for backflow 4343 on the top surface of the substrate 434 simultaneously. Exemplarily, the via holes 4347 are evenly distributed on the first ground for backflow 4343.

FIGS. 18 and 20 show the situations where that the first positive electrode 4332 and the second positive electrode 4333 are correspondingly connected to the first high-speed signal line 4341 and the second high-speed signal line 4342 via bonding wires, but when the first positive electrode 4332 and the second positive electrode 4333 of the dual laser chip 433 are connected to the first high-speed signal line and the second high-speed signal line by flip-chip welding, a structure of the substrate may refer to the substrate 434 shown in FIGS. 18 and 20.

In the laser provided in the embodiment of the present disclosure, the ridge waveguide 4331 on the dual laser chip 433 is connected to the first positive electrode 4332 and the second positive electrode 4333 for feeding of high-speed signals. The first high-speed signal line 4341 and the second high-speed signal line 4342 are arranged on the substrate 434, the first positive electrode 4332 and the second positive electrode 4333 of the dual laser chip 433 are correspondingly connected to the first high-speed signal line 4341 and the second high-speed signal line 4342, and therefore the high-speed signals fed into the ridge waveguide 4331 may produce a preset delay difference by means of the first high-speed signal line 4341 and the second high-speed signal line 4342. In this way, the high-speed signals to be fed into the ridge waveguide 4331 may have a preset time delay difference by passing through the first high-speed signal line 4341 and the second high-speed signal line 4342, so can be fed into the ridge waveguide 4331 with preset time delay difference; the high-speed signals with the preset time delay difference are fed into the ridge waveguide, first obtain a photoelectric oscillation in respective resonator cavities, and then realize a photoelectric oscillation effect. Taking advantage of the time delay difference of the fed high-speed signals, the high-speed modulated lights generated by the dual laser structure may have a specific phase difference; after being superimposed, the 3 dB bandwidth curve of the single laser may have a flattening effect at a higher frequency, so as to realize a compensation of the bandwidth curve of the laser chip at a higher frequency position, and to obtain a further improvement of the bandwidth and transmission rate and achieve a higher rate modulation.

What is claimed is:

1. An optical module, comprising:
a light emitting component for generating and outputting signal light, including a laser;
wherein the laser comprises:
a laser chip for generating signal light;
a substrate which is provided with a chip mounting groove in its top side, a circuit is laid on a top surface of the substrate, the laser chip is arranged in the chip mounting groove, with the laser chip being connected to the circuit via bonding wires;
wherein
a bottom of the chip mounting groove comprises a chip carrying surface;
a first deepening groove is provided at one side of the chip carrying surface, with a height difference between a bottom surface of the first deepening groove and the top surface of the substrate being greater than a height difference between the chip carrying surface and the top surface of the substrate; and/or, a second deepening groove is provided at the other side of the chip carrying surface, with the height difference between a bottom surface of the second deepening groove and the top surface of the substrate being greater than the height difference between the chip carrying surface and the top surface of the substrate; and
the laser chip is arranged on the chip carrying surface, and the first deepening groove and/or the second deepening groove are configured to keep out of the way of corners of the laser chip.

2. The optical module according to claim 1, wherein the chip mounting groove extends through the substrate.

3. The optical module according to claim 1, wherein the substrate comprises a top board and a bottom board, and the chip mounting groove is provided in the top board.

4. The optical module according to claim 3, wherein a first circuit is laid on an upper surface of the top board, a first extension circuit is laid on a lower surface of the top board, via holes are provided in the top board, such that the first circuit is connected to the first extension circuit through the via holes.

5. The optical module according to claim 4, wherein at least part of the first circuit is arranged on the chip carrying surface, and projections of at least part of the via holes onto the top surface of the substrate are located on the chip carrying surface.

6. The optical module according to claim 1, wherein a difference of the height difference between the chip carrying surface and the top surface of the substrate and the thickness of the laser chip is within ±10 μm.

7. The optical module according to claim 1, wherein the chip carrying surface is located at the center of the chip mounting groove.

8. The optical module according to claim 1, wherein a metal layer is provided on the chip carrying surface, with the metal layer being electrically connected to the bottom surface of the laser chip.

9. The optical module according to claim 1, wherein several electrodes are disposed on the upper surface of the laser chip, and several pads are disposed on the top surface of the substrate, with the electrodes being correspondingly connected to the pads via bonding wires.

10. The optical module according to claim 1, wherein the circuit on the top surface of the substrate comprises a first high-speed signal line, a second high-speed signal line and a first ground for backflow,
the laser chip comprises two light emitting chips, the top surface of which is provided with a first positive electrode and a second positive electrode, and the bottom surface of which is provided with a negative electrode;
wherein the first positive electrode is electrically connected to the first high-speed signal line, the second positive electrode is electrically connected to the second high-speed signal line, the negative electrode is electrically connected to the first ground for backflow, and the first high-speed signal line and the second high-speed signal line have different lengths, so that the high-frequency signals transmitted to the first positive electrode and the second positive electrode through the first high-speed signal line and the second high-speed signal line have a preset delay difference.

11. The optical module according to claim 10, wherein the first positive electrode is connected to the first high-speed signal line via bonding wires, and the second positive electrode connected to the second high-speed signal line via bonding wires; and
the negative electrode is connected to the first ground for backflow by soldering.

12. The optical module according to claim 10, wherein the first positive electrode is flip-chip connected to the first high-speed signal line, the second positive electrode is flip-chip connected to the second high-speed signal line, and the negative electrode is connected to the first ground for backflow via bonding wires.

13. The optical module according to claim 10, further comprising a first matching resistor and a second matching resistor, wherein the first matching resistor is arranged in series on the first high-speed signal line, being close to and electrically connected to the first positive electrode, and the second matching resistor is arranged in series on the second high-speed signal line, being close to and electrically connected to the second positive electrode.

14. The optical module according to claim 10, wherein the first high-speed signal line is a straight high-speed signal line, and the second high-speed signal line is a bended high-speed signal line.

15. The optical module according to claim 14, wherein the laser chip is arranged at one end of the substrate, and an end of the first high-speed signal line away from the laser chip is parallel to an end of the second high-speed signal line away from the laser chip.

16. The optical module according to claim 10, wherein the first ground for backflow is arranged around the first high-speed signal line and the second high-speed signal line; and
a second ground for backflow is disposed on the bottom surface of the substrate, and via holes are provided in the substrate, such that the first ground for backflow and the second ground for backflow are connected through the via holes.

17. The optical module according to claim 10, wherein the laser chip comprises a ridge waveguide, and the first positive electrode and the second positive electrode are electrically connected at different positions of the ridge waveguide, respectively.

18. An optical module, comprising:
a light emitting component for generating and outputting signal light, comprising a laser;
wherein the laser comprises:
a laser chip for generating signal light;
a substrate which is provided with a chip mounting groove in its top side, a circuit is laid on a top surface of the substrate, the laser chip is arranged in the chip mounting groove, with the laser chip being connected to the circuit via bonding wires;
wherein a bottom of the chip mounting groove comprises a chip carrying surface, at least part of a side of the chip carrying surface is provided with a deepening groove, with a height difference between a bottom surface of the deepening groove and the top surface of the substrate being greater than a height difference between the chip carrying surface and the top surface of the substrate; wherein the laser chip is arranged on the chip carrying surface, and the deepening groove is configured to keep out of the way of corners of the laser chip.

19. The optical module according to claim 18, wherein the circuit on the top surface of the substrate comprises a first high-speed signal line, a second high-speed signal line and a first ground for backflow,
the laser chip comprises two light emitting chips, the top surface of which is provided with a first positive electrode and the second positive electrode, and the bottom surface of which is provided with a negative electrode;
wherein the first positive electrode is electrically connected to the first high-speed signal line, the second positive electrode is electrically connected to the second high-speed signal line, the negative electrode is electrically connected to the first ground for backflow, and the first high-speed signal line and the second high-speed signal line have different lengths, so that the high-frequency signals transmitted to the first positive electrode and the second positive electrode through the first high-speed signal line and the second high-speed signal line have a preset delay difference.

20. The optical module according to claim 19, wherein the first high-speed signal line is a straight high-speed signal line, the second high-speed signal line is a bended high-speed signal line; the laser chip is disposed at one end of the substrate, and an end of the first high-speed signal line away from the laser chip is parallel to an end of the second high-speed signal line away from the laser chip; and
the first high-speed signal line extends from one end of the substrate to the other end of the substrate.
